(19) United States
(12) Patent Application Publication
(10) Pub. No.: US 2015/0060932 A1
(43) Pub. Date: Mar. 5, 2015

(54) LIQUID-FILLED PACKAGING STRUCTURE OF HEATING COMPONENT

(71) Applicant: INDUSTRIAL TECHNOLOGY RESEARCH INSTITUTE, Hsinchu (TW)

(72) Inventors: Meng-Chi HUANG, Zhongli City (TW); Wen-Hua ZHANG, Hsinchu County (TW); Tune-Hune KAO, Hsinchu (TW); Min-Chieh CHOU, Taipei (TW); Chih-Yu KO, Changhua City (TW)

(21) Appl. No.: 14/329,235

(22) Filed: Jul. 11, 2014

(30) Foreign Application Priority Data
Sep. 2, 2013 (TW) 102131580

(51) Int. Cl. H01L 33/64; H01L 25/075; H01L 33/56

(52) U.S. Cl. CPC H01L 33/648; H01L 33/641; H01L 33/644; H01L 33/56; H01L 25/0753; H01L 33/642
USPC 257/99

(57) ABSTRACT

A liquid-filled packaging structure of a heating component includes a main body, at least one heating component and a channel. The main body includes an accommodating space, a first opening connecting with the accommodating space and a second opening connecting with the accommodating space. The heating component is disposed in the accommodating space. The two opposite ends of the channel connect with the first opening and the second opening, respectively, so as to form a circulation loop. The accommodating space and the channel are filled with a liquid.

### CROSS-REFERENCE TO RELATED APPLICATIONS

This non-provisional application claims priority under 35 U.S.C. §119(a) on Patent Application No(s). 102131580 filed in Taiwan, R.O.C. on Sep. 2, 2013, the entire contents of which are hereby incorporated by reference.

### BACKGROUND

1. Technical Field

The disclosure relates to a liquid-filled packaging structure of a heating component.

2. Related Art

Ultraviolet light sources (UV light source) are commonly used in different kinds of applications based on their wave bands. The use of mercury has been restricted according to the Restriction of Hazardous Substances Directive (RoHS) adopted by European Union, therefore, UV Light-Emitting Diode (UV LED) will replace the mercury lamp in the near future. However, the package of the UV LED has two main problems. One is that the low conversion efficiency of the UV LED die (namely, chip crystal) leads to produce too much heat, thus, an effective heat dissipation mechanism needs to be applied to the UV LED lamp, to improve the stabilization and the life span of the LED. For example, a substrate with high conduction efficiency, e.g., aluminum nitride substrate (the heat conduction coefficient is 200 to 240 W/m K), is applied for enhancing the heat dissipation to immediately protect the LED from concentrating the heat at one point, generating a hot spot. The other problem is that because the light emitting wave band of the UV LED is between 300 to 400 nanometers (nm), encapsulants or lenses made of epoxy or silicone for the package of LED, are illuminated by the UV (especially the UV LED emitting the light having short wavelength) over time, so as to hurt or damage the good condition of the UV LED or to be degenerated (become yellowed). Thus, the luminance and color temperature of the UV LED are reduced.

The conventional package manner of the UV LED is to package the LED die in a vacuum or an inert gas environment for protecting the electrodes on the surface of the LED Die. However, the disadvantage of such a manner is that the index of refraction of the light emitted from the LED die is so high that the efficiency becomes lowered. In addition, the packaging manner in the vacuum or the inert gas environment leads to higher costs and a lower life span.

### SUMMARY

An embodiment of the disclosure provides a liquid-filled packaging structure of a heating component comprising a main body, at least one heating component and a channel. The main body includes an accommodating space, a first opening connecting with the accommodating space and a second opening connecting with the accommodating space. The heating component is disposed in the accommodating space. The two opposite ends of the channel connect with the first opening and the second opening, respectively, so as to form a circulation loop. The accommodating space and the channel are filled with a liquid.

### BRIEF DESCRIPTION OF THE DRAWINGS

The present disclosure will become more fully understood from the detailed description given hereinbelow along with the accompanying drawings which are for illustration only, thus are not limitative of the present disclosure, and wherein:

FIG. 1A is a cross-sectional view of a liquid-filled packaging structure of a heating component according to a first embodiment of the disclosure;

FIG. 1B is a cross-sectional view along a line A-A in FIG. 1A;

FIG. 2 is a cross-sectional view of a liquid-filled packaging structure of a heating component according to a second embodiment of the disclosure;

FIG. 3 is a cross-sectional view of a liquid-filled packaging structure of a heating component according to a third embodiment of the disclosure;

FIG. 4 is a cross-sectional view of a liquid-filled packaging structure of a heating component according to a fourth embodiment of the disclosure;

FIG. 5 is a cross-sectional view of a liquid-filled packaging structure of a heating component according to a fifth embodiment of the disclosure;

FIG. 6 is a cross-sectional view of a liquid-filled packaging structure of a heating component according to a sixth embodiment of the disclosure;

FIG. 7 is a diagram illustrating the relationships between the temperature and the start time of a liquid-filled packaging structure of a heating component and an LED lamp without a circulation channel; and

FIG. 8 is a cross-sectional view of a liquid-filled packaging structure of a heating component according to a seventh embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

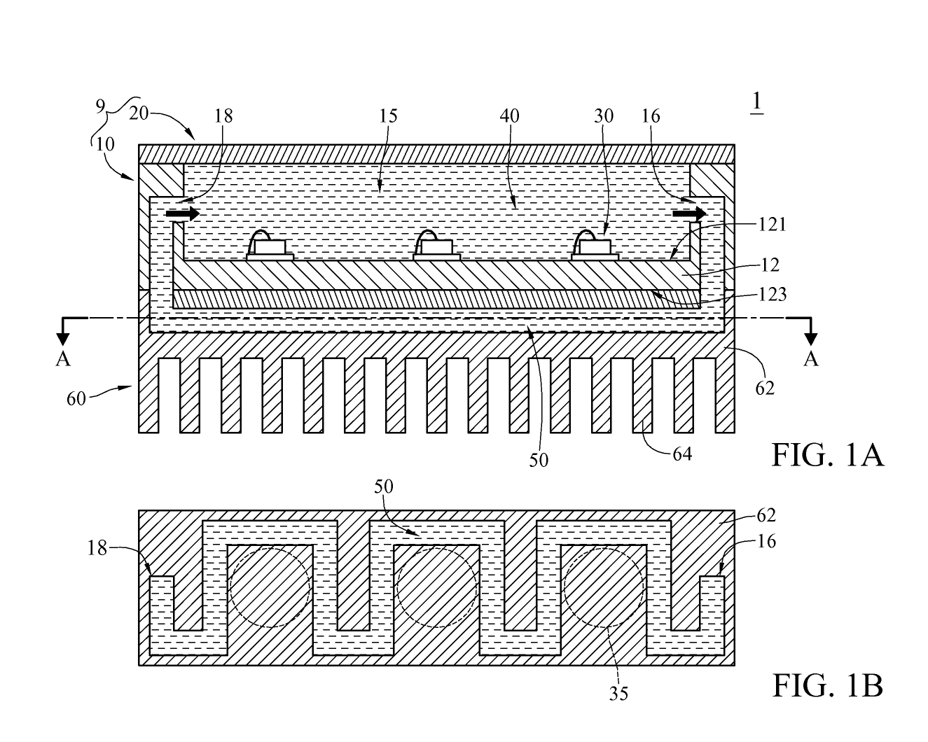

Please refer to FIG. 1A, which is a cross-sectional view of a liquid-filled packaging structure of a heating component according to a first embodiment of the disclosure. The liquid-filled packaging structure of a heating component 1 in this embodiment comprises a main body 9, at least one heating component 30, a heat dissipation component 60 and a channel 50. The main body 9 includes an accommodating space 15, a first opening 16 connecting with the accommodating space 15 and a second opening 18 connecting with the accommodating space 15. In this embodiment, the main body 9 includes a frame 10 and a cover 20. The frame 10 includes a substrate 12 having a first surface 121 and a second surface 123 that are opposite to each other. The first surface 121 forms one of walls of the accommodating space 15. The cover 20 covers the frame 10 so as to form the accommodating space 15 together. The accommodating space 15 and the channel 50 are filled with a liquid 40. In this embodiment, the first opening 16 and second opening 18 are formed on the frame 10, but are not limitative for the disclosure. In other embodiments, the first opening 16 and the second opening 18 are both formed on the cover 20 or formed on the frame 10 and cover 20, respectively.

In this embodiment, the heating component 30 is disposed on the first surface 121 of the substrate 12. The heating component 30 further comprises electronic components including dies, circuit boards, transmission wires and so forth, but are not limitative of the disclosure. The electronic components, for example, are resistors, capacitors, diodes, transistors, integrated circuits, fuel cells or solar cells. The circuit boards, for example, are ceramic substrates or printed circuit boards (PCB). In this embodiment, three LED dies are taken as the heating components 30 for example and are not limitative of the disclosure. In other embodiments, the number of the heating components 30 may be more than or less than three.

The channel 50 is connected to the first opening 16 and the second opening 18 of the frame 10. The cover 20 covers the frame 10 so as to form the accommodating space 15 together. The accommodating space 15 and the channel 50 are both filled with the liquid 40.

The heat dissipation component 60 is disposed on the second surface 123 of the frame 10. The above-mentioned “being disposed on the second surface 123” is defined as the heat dissipation component 60 is attached to the second surface 123 of the frame 10 or the heat dissipation component 60 is located on the same side of the frame 10 as the second surface 123 and separated with the second surface 123 by a distance. In this embodiment, the heat dissipation component 60 is attached to the second surface 123 of the frame 10, but this configuration is not limited to the disclosure.

The heat dissipation component 60 is a heat sink having a plurality of fins or is a thermoelectric component (TEC). The cover 20 is made of transparent material, e.g., inorganic material including silicone, glass, quartz glass and so forth. The liquid 40 is a material with low polarity, which is selected from a group consisting of silicone oil, mineral oil, and organic ester and a combination thereof. In addition the viscosity of the liquid 40 is between 0.1 to 10⁵ centipoises (cP). However, the above-mentioned materials are only for exemplary, and are not limitative of the disclosure. In this embodiment, the heat dissipation component 60 is a heat sink comprising a base 62 and a plurality of fins 64. The base 62 is connected to the second surface 123 of the substrate 12 of the frame 10, and the channel 50 extends through the base 62.

Please refer to FIGS. 1A and 1B together, and FIG. 1B is a cross-sectional view along a line A-A in FIG. 1A. In this embodiment, the heating components 30 are a plurality of LED dies. When light generated by the heating component 30 emits out of the cover 20 through the liquid 40, heat generated by the heating components 30 transfers to the base 62 of the heat dissipation component 60 through an effective heat dissipation area 35. Then, the heat is dissipated through the fin 64, reducing the whole temperature of the liquid-filled packaging structure of the heating component 1. In this disclosure, the effective heat dissipation area 35 is defined as an area of the base 62 on which the heat source of the heating component 30 projects. For example, the heat generated by the heating component 30 is spread from the thermal contact area, where the first surface 121 of the substrate 12 is in thermal contact with the heating component 30, towards the second surface 123 of the substrate 12. The following describes an exemplary embodiment that the angle of the thermal spread of the heating component 30 is forty-five degrees. The effective heat dissipation area 35 (as shown in FIG. 1B) is an area that the bottom area of the heating component 30, in thermal contact with the first surface 121, projects and expands along forty-five degrees to the base 62, but the angle of the thermal spread of the heating component 30 is not limitative of the disclosure.

The liquid-filled packaging structure of the heating component 1 in this embodiment applies not only the thermal conduction between the heat dissipation component 60 and the substrate 12 but also the thermosyphon by the liquid 40. Specifically, the liquid 40, in thermal contact with the heating component 30, is configured for flowing through the channel 50. After performing heat exchange with the heat source (the heating components 30), the liquid 40 flows into the channel 50 and the heat of the liquid 40 is removed to the heat dissipation component 60 through the channel 50. Then, the liquid 40 flows back to the heating component 30 to form a circulation loop for heat dissipation. Therefore, the heat dissipation efficiency of the liquid-filled packaging structure of the heating component 1 is enhanced by the circulation loop.

In this embodiment, when the liquid 40 is heated, the volume of the liquid 40 expands and its density lowers. Accordingly, the buoyancy of the heated liquid 40 is greater than that of the liquid 40 at lower temperature, so the heated liquid 40 flows upwards (towards the cover 20), generating the thermal convection of the liquid 40. Because the liquid 40 is filled within an enclosed chamber formed by the channel 50 and the accommodating space 15, in this enclose chamber, once the liquid 40 at high temperature flows, it drives the adjacent liquid 40 at low temperature fills the empty space left by the liquid 40 at high temperature, which enhances the circulation of the liquid 40 around the channel 50 and the accommodating space 15. The liquid 40 at high temperature flows into the channel 50 through the first opening 16. Because the channel 50 is disposed inside and extends through the base 62 of the heat dissipation component 60, the heat of the liquid 40 at high temperature inside the channel 50 is dissipated by the fins 64 of the heat dissipation component 60 so as to lower the temperature of the liquid 40. Then, the liquid 40 at a low temperature flows back to the accommodating space 15 through the second opening 18. Therefore, the liquid 40 may circulate around the liquid-filled packaging structure of the heating component 1 to remove the heat generated by the heating components 30.

In order to improve the heat dissipation efficiency of the liquid-filled packaging structure of the heating component 1, the channel 50 is designed to be serpentine shape that the channel comprises a plurality of U shapes connected with each other with respect to the cross-sectional area line A-A in FIG. 1A, for increasing the thermal contact area between the liquid 40 and the heat dissipation component 60. In this embodiment, the U shapes of the channel and the effective heat dissipation area 35 on the base 62 are separated with each other (i.e., the U shapes of the channel do not intersect with the effective heat dissipation area 35 on the base 62), for enhancing the use of the space of the base 62 as well as the efficacy of the heat dissipation component 60. In this disclosure, the heat dissipation component 60 has no impact on the area of the base 62 except the effective heat dissipation area 35, so the area of heat dissipation component 60 where the channel 50 flows through does not affect the heat transfer between the substrate 12 and the base 62. In other embodiments, in order to enhance the circulation efficiency of the liquid 40, the widths of the plurality of U shapes gradually decrease from the first opening 16 towards the second opening. Thus, the flow resistance of the accommodating space 15 at the second opening 18 end is increased, allowing the liquid 40 at a high temperature to flow towards the first opening 16 end of the accommodating space 15.

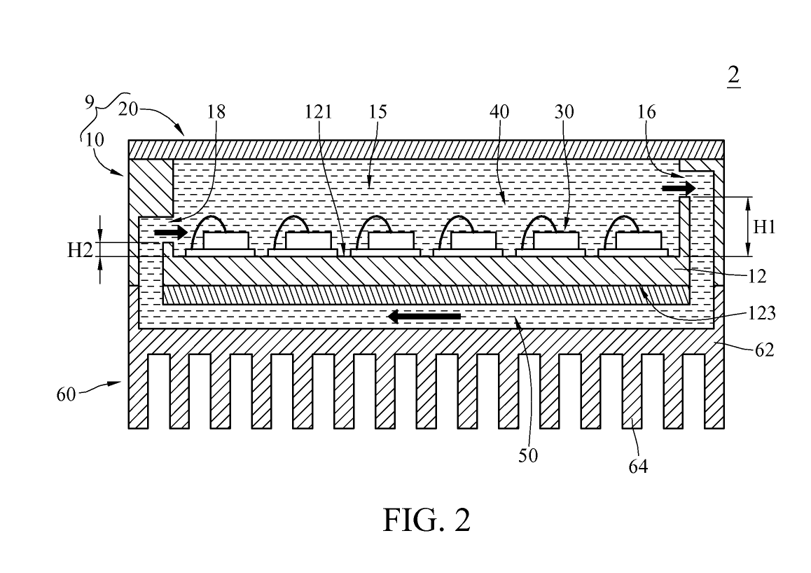

Please refer to FIG. 2, which is a cross-sectional view of a liquid-filled packaging structure of the heating component according to a second embodiment of the disclosure. In this embodiment, the difference between the liquid-filled packaging structure of the heating component 2 and the liquid-filled packaging structure of the heating component 1 in FIG. 1A is that the first opening 16 and the second opening 18 of the liquid-filled packaging structure of the heating component 2 have different heights. In this embodiment, the first opening 16 and the first surface 121 are separated by a first height H1, the second opening 18 and the first surface 121 are separated by a second height H2, and the first height H1 is greater than the second height H2. That is to say, adjusting the height of the opening makes the flow resistance of the first opening 16 end less than that of the second opening 18 end, so the liquid 40 at high temperature inside the accommodating space 15 tends to flow towards the first opening 16, which improves the circulation efficiency of the liquid 40.

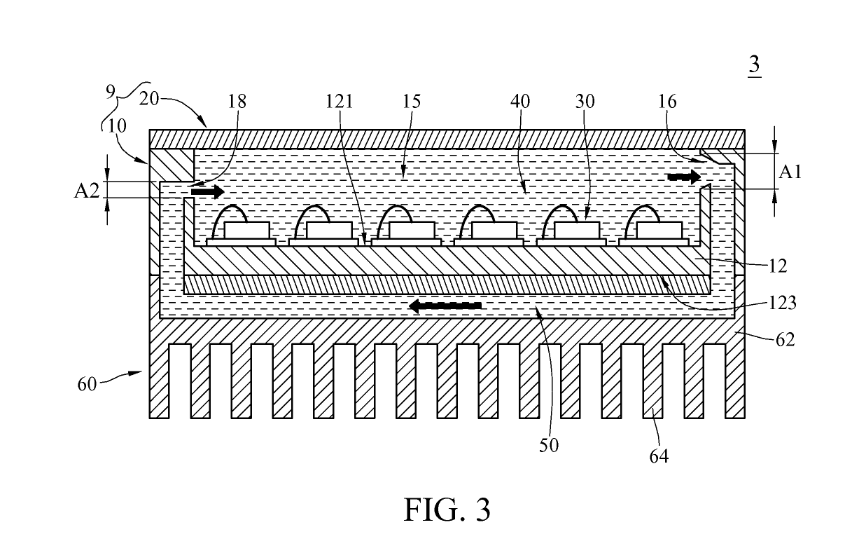

Please refer to FIG. 3, which is a cross-sectional view of a liquid-filled packaging structure of the heating component according to a third embodiment of the disclosure. In this embodiment, the difference between the liquid-filled packaging structure of the heating component 3 and the liquid-filled packaging structure of the heating component 1 in FIG. 1A is that the first opening 16 and the second opening 18 of liquid-filled packaging structure of the heating component 3 have different cross-sectional areas. In this embodiment, the first cross-sectional area A1 of the first opening 16 is greater than the second cross-sectional area A2 of the second opening 18. That is to say, adjusting the cross-sectional areas of the openings makes the flow resistance of the first opening 16 end less than that of the second opening 18 end, so the liquid 40 at a high temperature inside the accommodating space 15 tends to flow towards the first opening 16, improving the circulation efficiency of the liquid 40.

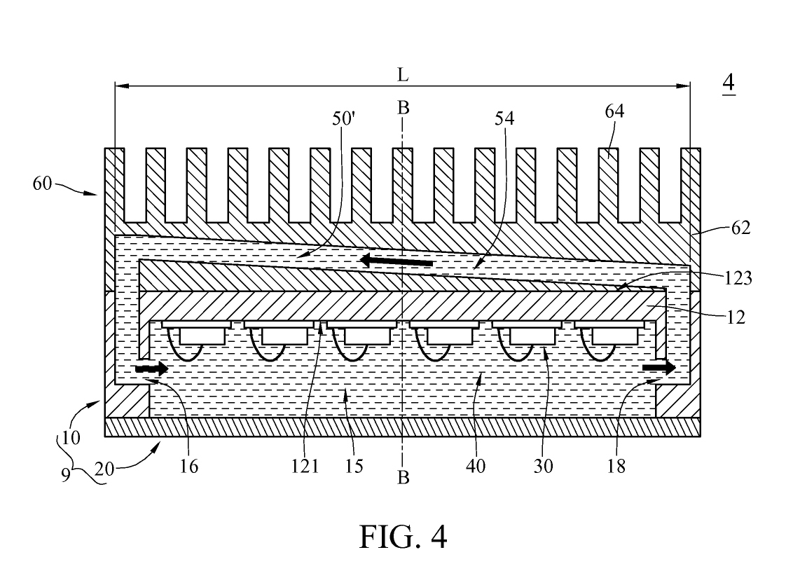

Please refer to FIG. 4, which is a cross-sectional view of a liquid-filled packaging structure of the heating component according to a fourth embodiment of the disclosure. In this embodiment, the difference between the liquid-filled packaging structure of the heating component 4 and the liquid-filled packaging structure of the heating component 1 in FIG. 1A is that the heating component 30 of the liquid-filled packaging structure of the heating component 4 is disposed toward the ground, i.e., the liquid-filled packaging structure of the heating component 4 system is upside down with respect to the configuration of the liquid-filled packaging structure of the heating component 1. Moreover, the configuration of the channel 50′ is different from the channel 50 of the liquid-filled packaging structure of the heating component 1 in FIG. 1A. In this embodiment, the lengths of the two ends of the channel 50′ are not equal to each other. Specifically, the length L, which the channel 50′ projects in the horizontal direction in FIG. 4, is equally divided by the middle line B-B, so the channel 50′ is divided into a first-opening-16-end section (on the left side of the middle line B-B) and a second-opening-18-end section (on the right side of the middle line B-B). The channel length of the first-opening-16-end section is greater than that of the second-opening-18-end, i.e., the path length of the liquid 40 flows through the first opening 16 end is greater than that of the second opening 18. The configuration of the channel 50′ differentiates the channel lengths of the first opening 16 end and the second opening 18 end, so as to differentiate the flow resistances of the first opening 16 end and that of the second opening 18 end, driving the liquid 40 in the channel 50′ to flow towards the second opening 18 end as well as driving the liquid 40 at high temperature in the accommodating space 15 to flow towards the first opening 16. Therefore, the circulation efficiency of the liquid 40 is improved.

According to the above-mentioned embodiments in FIGS. 2 to 4, The configuration of the channel 50 is asymmetrical that the shape of the first opening 16 end of the channel 50 is different from that of the second opening 18 end of the channel 50 (or 50′), which differentiates the flow resistances of the channel of the first opening 16 and that of the second opening 18, thereby driving the liquid 40 in the channel 50 (or 50′) to flow towards the end of the opening with less flow resistance. The above-mentioned asymmetrical manners of the channel 50 (or 50′) comprise asymmetrical lengths, asymmetrical inner diameters of the channel and asymmetrical horizontal heights. However, people skilled in the art may apply other asymmetrical manners to achieve the same purpose, and are not limitative of the above-mentioned asymmetrical manners.

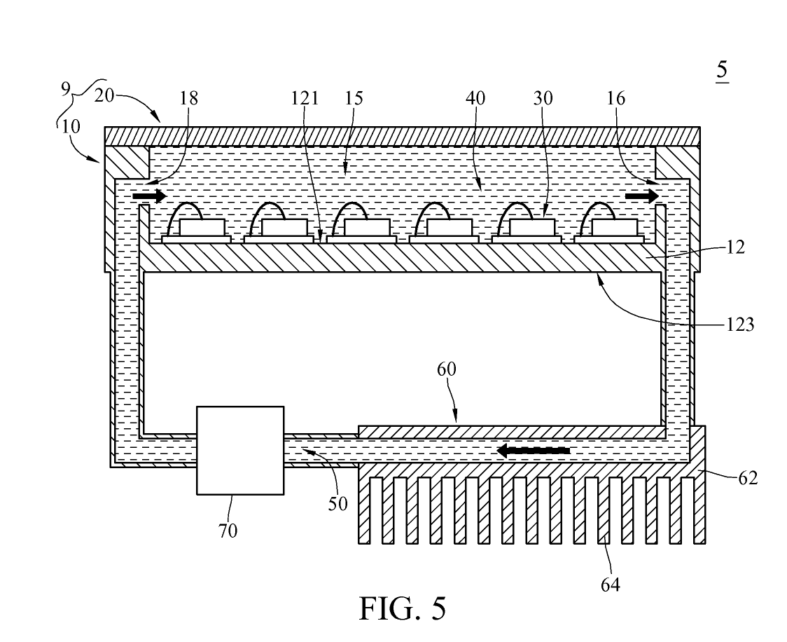

Please refer to FIG. 5, which is a cross-sectional view of a liquid-filled packaging structure of the heating component according to a fifth embodiment of the disclosure. In this embodiment, the difference between the liquid-filled packaging structure of the heating component 5 and the liquid-filled packaging structure of the heating component 1 in FIG. 1A is that the heat dissipation component 60 is disposed on the same side of the frame 10 as the second surface 123, but the base 62 and the substrate 12 of the frame 10 are not directly connected with each other, i.e., the base 62 and the second surface 123 of the substrate 12 are separated by a distance. In addition, the liquid-filled packaging structure of the heating component 5 further comprises a pump 70 disposed inside the channel 50. The pump 70 is configured for driving the liquid 40 in the channel 50 to flow towards the second opening 18 end, enhancing the circulation efficiency of the liquid 40.

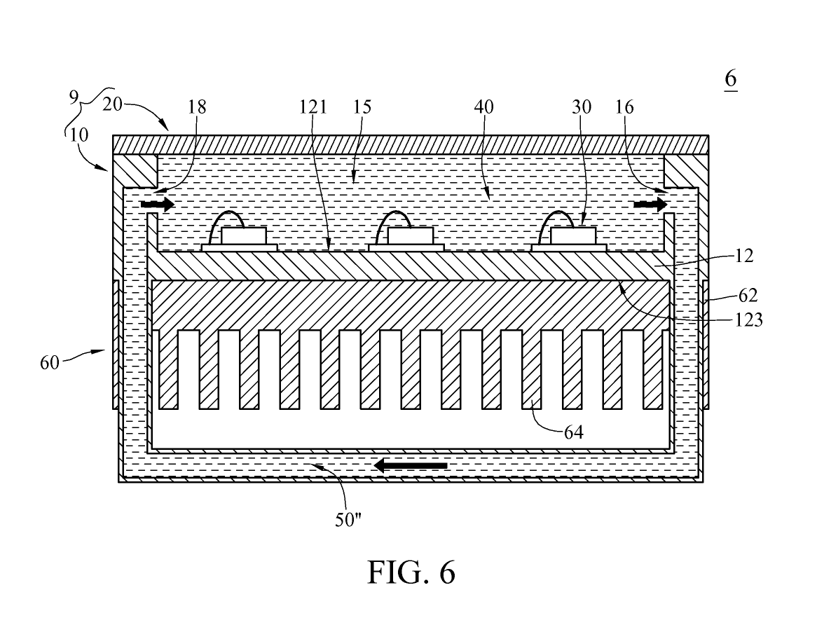

Please refer to FIG. 6, which is a cross-sectional view of a liquid-filled packaging structure of the heating component according to a sixth embodiment of the disclosure. The difference between the liquid-filled packaging structure of the heating component 6 and the liquid-filled packaging structure of the heating component 1 in FIG. 1A is that after extending through the base 62, the channel 50″ extends through to the outside of the heat dissipation component 60. Because the channel 50″ extends through to the outside of the heat dissipation component 60, the heat dissipation efficiency of the liquid-filled packaging structure of the heating component 6 is improved.

The liquid-filled packaging structure of the heating component 6 according to this embodiment of the disclosure is to encapsulate the heating component in the accommodating space 15 filled with the liquid 40, such that the heating component 30 (e.g., the LED die) is in direct contact with the liquid 40, and the light emitted by the heating component 30 is refracted when passing through the liquid 40. Thus, adjusting the index of the refraction of the liquid based on what kind of the heating component 30 (e.g., the LED die) the liquid-filled packaging structure of the heating component applies may enhance the efficiency of light extraction of the LED lamp. For example, the liquid 40 is silicone oil, and the heating component, which emits blue ray having the wavelength of 465 nm, is encapsulated by the liquid of silicone oil. After the heating component 30 operates to emit light for a continuous 72 hours by the power of 3.3 voltage and 350 milliamps and 28 degrees Celsius of room temperature, the total radiation flux is increased from 330.83 milliwatts to 369.38 milliwatts, which increases by 11.65 percent.

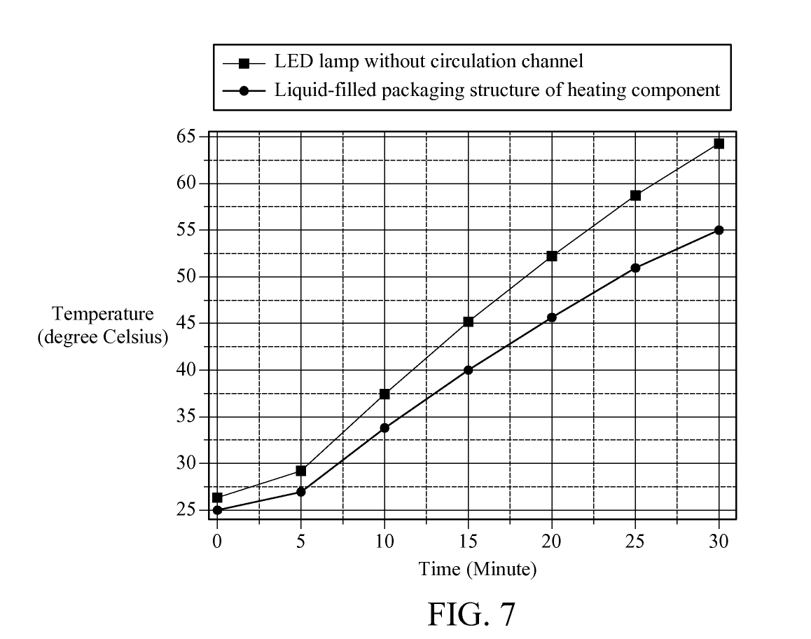

Please refer to FIG. 7, which is a diagram illustrating the relationships between the temperature and the start time of the liquid-filled packaging structure of the heating components 1-6 (the heating components 30 are LED dies for example) and an LED lamp without a circulation channel. It is found in FIG. 7 that the increase rate of the temperature of the LED lamp without the circulation channel is faster than that of the liquid-filled packaging structure of the heating components provided by this disclosure. The difference of the temperature between them is ten degrees Celsius after the LED operates for thirty minutes. Thus, FIG. 7 shows the efficacy of heat dissipation of the channel provided by this disclosure.

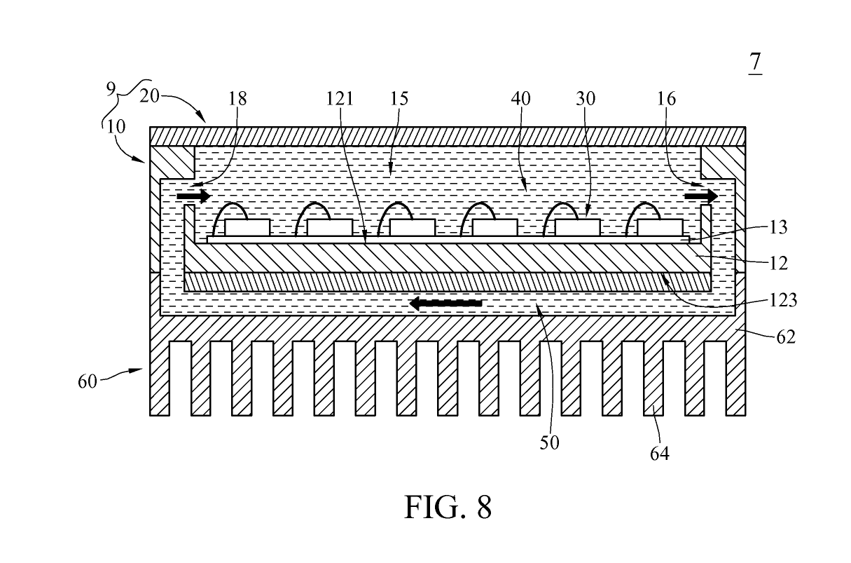

Please refer to FIG. 8, which is a cross-sectional view of a liquid-filled packaging structure of a heating component according to a seventh embodiment of the disclosure. The difference between the liquid-filled packaging structure of the heating component 7 and the liquid-filled packaging structure of the heating component 1 in FIG. 1A is that the liquid-filled packaging structure of the heating component 7 further comprises a metal printed circuit board (MCPCB) 13 disposed between the heating component 30 and the substrate 12, and the heating component 30 is electrically connected to the metal printed circuit board 13.

The liquid-filled packaging structure of the heating component (the heating components 30 are LED dies for example) according to the embodiments of the disclosure, the liquid is packaged to be in direct contact with the heating component (i.e., the heating component is immersed in the liquid), and the asymmetrical configuration of the channel or the drive of the pump allows the liquid to circulate around the liquid-filled packaging structure of the heating component, improving the thermal management, the light extraction, as well as maintaining the condition of encapsulant of the heating component and stabilization of the packaging structure (i.e., the heating component), which are described as follows:

(1) Thermal management: the heat is removed form the heat source to the outside by the liquid through the channel. After being cooled down, the liquid circulates to flow back to the heating component having a higher temperature than the channel by the configuration of the channel that the contact area between the liquid at a higher temperature and the cold end (ambient environment) is greatly increased. Thus, the path of the thermal spread is increased, and it controls the rising temperature of the heating component.

(2) Light extraction: the index of refraction of the liquid matches with the heating components. Compared with the package manner of the UV LED module in the inert gases or vacuum environment, the liquid package manner provided in this disclosure may greatly increase its efficiency of light extraction by 10 percent.

(3) Maintain the condition of encapsulant: adjusting the flow velocity of the liquid may control the light absorbing flux per certain time of the liquid. The liquid-filled packaging structure of the heating component may prevent the encapsulant or other packaging material of the heating component (e.g., LED) from being degenerated or yellowed according to the pyrolysis kinetics, or may defer the degeneration or yellowing of the encapsulants. Moreover, the liquid-filled packaging structure of the heating component may further comprise a door located on the frame or the channel for replacing the liquid. Therefore, when the liquid-filled packaging structure of the heating component operates for a long time, the liquid may be tainted or blemished, so the used liquid may be replaced through the door to maintain the life span and performance of the LED lamp.

(4) The stabilization of the packaging structure: the packaging structure (i.e., the heating component) is totally immersed in the liquid of the accommodating space, each unit of the packaging structure is borne by an equaled stress in the liquid. During the heat exchange process, this equaled stress may prevent the packaging structure from fracturing from the thermal stress, such as, thermal creep at the interface between two substances and the fatigue of the material. Thus the liquid may protect the packaging structure.

What is claimed is:

1. A liquid-filled packaging structure of a heating component, comprising:
a main body including an accommodating space, a first opening connecting with the accommodating space and a second opening connecting with the accommodating space;
at least one heating component disposed in the accommodating space; and
a channel, the two opposite ends of the channel connecting with the first opening and the second opening, respectively, so as to form a circulation loop, and wherein the accommodating space and the channel are filled with a liquid.

2. The liquid-filled packaging structure of the heating component according to claim 1, wherein the main body further comprises a frame and a cover covering the frame so as to form the accommodating space together, the frame further comprises a substrate including a first surface and a second surface that are opposite to each other, the first surface forms one of walls of the accommodating space, and the heating component is disposed on the first surface.

3. The liquid-filled packaging structure of the heating component according to claim 2, further comprising a heat dissipation component disposed on the second surface of the frame.

4. The liquid-filled packaging structure of the heating component according to claim 3, wherein the heat dissipation component comprises a base and a plurality of fins, and the channel extends through the base.

5. The liquid-filled packaging structure of the heating component according to claim 3, wherein the channel extends through to the outside of the heat dissipation component.

6. The liquid-filled packaging structure of the heating component according to claim 4, wherein the base of the heat dissipation component is connected to the second surface of the frame.

7. The liquid-filled packaging structure of the heating component according to claim 2, wherein the channel is asymmetrical.

8. The liquid-filled packaging structure of the heating component according to claim 7, wherein a first height between the first opening and the first surface is greater than a second height between the second opening and the first surface.

9. The liquid-filled packaging structure of heating component according to claim 7, wherein a channel length of the channel adjacent to the first opening is greater than a channel length of the channel adjacent to the second opening.

10. The liquid-filled packaging structure of the heating component according to claim 1, wherein the channel is asymmetrical.

11. The liquid-filled packaging structure of the heating component according to claim 10, the channel is serpentine shaped so that the channel comprises a plurality of U shapes connected with each other.

12. The liquid-filled packaging structure of the heating component according to claim 11, wherein the widths of the plurality of U shapes gradually decrease from the first opening towards the second opening.

13. The liquid-filled packaging structure of the heating component according to claim 10, wherein the cross-sectional area of the first opening is greater than the cross-sectional area of the second opening.

14. The liquid-filled packaging structure of the heating component according to claim 1, further comprising a pump disposed in the channel.

15. The liquid-filled packaging structure of the heating component according to claim 1, wherein the liquid is selected from a group consisting of silicone oil, mineral oil, and organic ester and a combination thereof.

16. The liquid-filled packaging structure of the heating component according to claim 15, wherein the viscosity of the liquid is between 0.1 and 10⁵ cp.

17. The liquid-filled packaging structure of the heating component according to claim 1, wherein the heating component is a light emitting diode die.
